(19) United States
(12) Patent Application Publication
(10) Pub. No.: US 2019/0198336 A1
(43) Pub. Date: Jun. 27, 2019

(54) ETCHING METHOD

(71) Applicant: Tokyo Electron Limited, Tokyo (JP)

(72) Inventors: Yoshimitsu Kon, Kurokawa-gun (JP); Yoshihiro Asayama, Kurokawa-gun (JP); Suguru Atsumi, Kurokawa-gun (JP)

(21) Appl. No.: 16/232,202

(22) Filed: Dec. 26, 2018

(30) Foreign Application Priority Data
Dec. 27, 2017 (JP) 2017-251560

(51) Int. Cl. H01L 21/3065; H01L 21/308; H01L 21/311; H01L 21/67; H01J 37/32

(52) U.S. Cl. CPC H01L 21/3065; H01L 21/3085; H01L 21/31116; H01L 21/31144; H01J 37/32724; H01J 37/32449; H01J 2237/334; H01J 37/32642; H01L 21/67069

(57) ABSTRACT

In an etching method, plasma of a first processing gas and plasma of a second processing gas are alternately generated. Each of the first processing gas and the second processing gas includes a first gas containing first fluorocarbon, a second gas containing second fluorocarbon, an oxygen-containing gas and a fluorine-containing gas. A ratio of a number of fluorine atoms to a number of carbon atoms in a molecule of the second fluorocarbon is larger than that in a molecule of the first fluorocarbon. When a flow rate of the first gas is increased, a flow rate of the second gas is decreased. When a flow rate of the second gas is increased, a flow rate of the first gas and a flow rate of the fluorine-containing gas are decreased and a flow rate of the oxygen-containing gas is increased.

### CROSS-REFERENCE TO RELATED APPLICATION

This application claims the benefit of Japanese Patent Application No. 2017-251560 filed on Dec. 27, 2017, the entire disclosures of which are incorporated herein by reference.

### TECHNICAL FIELD

The various aspects and embodiments described herein pertain generally to an etching method.

### BACKGROUND

In the manufacture of an electronic device, plasma etching is performed to transfer a pattern of a mask to a film of a substrate. In the plasma etching, it is required to etch the film selectively with respect to the mask. That is, selectivity is required in the plasma etching.

To achieve high selectivity, there is known an etching method of generating plasma of two kinds of processing gases alternately. One of these two processing gases is a deposition gas, and the other is an etching gas. That is, the one processing gas has higher deposition property than the other. If the plasma of the deposition gas is generated, a deposit is formed on the mask. In the etching of the film with the plasma of the etching gas, the mask is protected by the deposit. This etching method is described in Patent Document 1.

In the etching method disclosed in Patent Document 1, plasma etching under a first processing condition and plasma etching under a second processing condition are alternately performed. Both a first processing gas used in the first processing condition and a second processing gas used in the second processing condition include a C₄F₈ gas and a C₄F₆ gas. A flow rate of the C₄F₆ gas in the first processing condition is larger than a flow rate of the C₄F₆ gas in the second processing condition, and a flow rate of the C₄F₈ gas in the second processing condition is larger than a flow rate of the C₄F₈ gas in the first processing condition.

Patent Document 1: Japanese Patent Laid-open Publication No. 2012-039048

As stated above, in the plasma etching, the film needs to be etched selectively against the mask, that is, selectivity is required. In the plasma etching with the two kinds of fluorocarbon gases as disclosed in Patent Document 1, it is still required to improve the selectivity.

### SUMMARY

In one exemplary embodiment, there is provided an etching method of etching a film of a substrate. The substrate has a mask provided with a pattern on the film. The etching method is performed in a state that the substrate is placed in a chamber of a plasma processing apparatus. The etching method comprises (i) generating plasma of a first processing gas including a first gas containing first fluorocarbon, a second gas containing second fluorocarbon, an oxygen-containing gas and a fluorine-containing gas within the chamber to etch the film; and (ii) generating plasma of a second processing gas including the first gas, the second gas, the oxygen-containing gas and the fluorine-containing gas within the chamber to etch the film. The generating of the plasma of the first processing gas and the generating of the plasma of the second processing gas are performed alternately. A ratio of a number of fluorine atoms to a number of carbon atoms in a molecule of the second fluorocarbon is larger than a ratio of the number of fluorine atoms to the number of carbon atoms in a molecule of the first fluorocarbon. A flow rate of the first gas in the first processing gas is larger than a flow rate of the first gas in the second processing gas. A flow rate of the second gas in the second processing gas is larger than a flow rate of the second gas in the first processing gas. A flow rate of the oxygen-containing gas in the second processing gas is larger than a flow rate of the oxygen-containing gas in the first processing gas. A flow rate of the fluorine-containing gas in the second processing gas is smaller than a flow rate of the fluorine-containing gas in the first processing gas.

In the etching method, an overshoot and an undershoot in a time characteristic of an emission intensity of fluorine in the plasma and a time characteristic of an emission intensity of oxygen in the plasma are suppressed. Further, each of the emission intensity of the fluorine in the plasma and the emission intensity of the oxygen in the plasma increases or decreases as time passes by. That is, it is possible to increase or decrease density of plasma of the fluorine and density of plasma of the oxygen with a lapse of time while suppressing an excessive variation in the density of the plasma of the fluorine and the density of the plasma of the oxygen. Thus, the amount of the carbon-containing material deposited on the mask can be controlled. Therefore, it becomes possible to etch the film selectively with respect to the mask, that is, to achieve the high selectivity.

A high frequency power for generation of the plasma of the first processing gas and generation of the plasma of the second processing gas is continuously supplied through the generating of the plasma of the first processing gas and the generating of the plasma of the second processing gas.

The flow rate of the first gas in the first processing gas is larger than the flow rate of the second gas in the first processing gas, and the flow rate of the second gas in the second processing gas is larger than the flow rate of the first gas in the second processing gas.

The first fluorocarbon is perfluorocarbon or hydrofluorocarbon, and the second fluorocarbon is perfluorocarbon or hydrofluorocarbon. The first fluorocarbon may be C₄F₆ and the second fluorocarbon may be C₄F₈. The oxygen-containing gas may be an oxygen gas (O₂ gas). The fluorine-containing gas may be a NF₃ gas.

According to the exemplary embodiment as stated above, it is possible to etch the film more selectively with respect to the mask, that is, to achieve the high selectivity.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a flowchart illustrating an etching method according to an exemplary embodiment;

FIG. 2 is a partially enlarged cross sectional view illustrating an example of a substrate to which the etching method shown in FIG. 1 is applicable;

FIG. 3 is a diagram schematically illustrating an example of a plasma processing apparatus which can be used to perform the etching method shown in FIG. 1;

FIG. 4 is a timing chart regarding the etching method shown in FIG. 1;

FIG. 5A is a graph showing a time characteristic of an emission intensity of a wavelength of 704 nm measured in a first experiment; FIG. 5B, a graph showing a time characteristic of an emission intensity of a wavelength of 777 nm measured in the first experiment; and FIG. 5C, a graph showing a time characteristic of an emission intensity of a wavelength of 516 nm measured in the first experiment;

FIG. 6A is a graph showing a time characteristic of an emission intensity of a wavelength of 704 nm measured in a second experiment; FIG. 6B, a graph showing a time characteristic of an emission intensity of a wavelength of 777 nm measured in the second experiment; and FIG. 6C, a graph showing a time characteristic of an emission intensity of a wavelength of 516 nm measured in the second experiment;

FIG. 7A is a graph showing a time characteristic of an emission intensity of a wavelength of 704 nm measured in a first comparative experiment; FIG. 7B, a graph showing a time characteristic of an emission intensity of a wavelength of 777 nm measured in the first comparative experiment; and FIG. 7C, a graph showing a time characteristic of an emission intensity of a wavelength of 516 nm measured in the first comparative experiment; and

FIG. 8A is a graph showing a time characteristic of an emission intensity of a wavelength of 704 nm measured in a second comparative experiment; FIG. 8B, a graph showing a time characteristic of an emission intensity of a wavelength of 777 nm measured in the second comparative experiment; and FIG. 8C, a graph showing a time characteristic of an emission intensity of a wavelength of 516 nm measured in the second comparative experiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described in detail with reference to the accompanying drawings. In the various drawings, same or corresponding parts will be assigned same reference numerals.

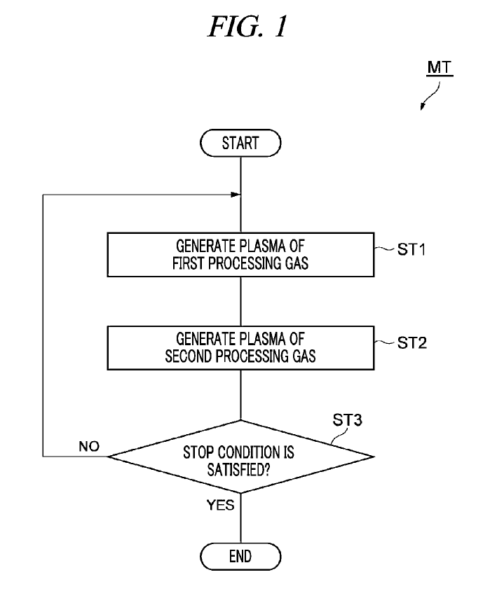

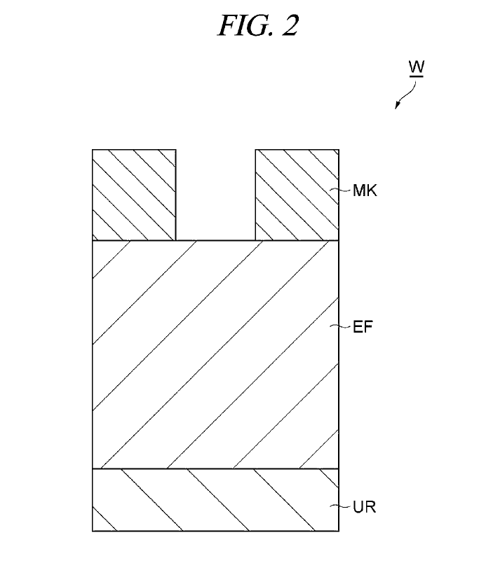

FIG. 1 is a flowchart for describing an etching method according to an exemplary embodiment. The etching method (hereinafter, referred to as “method MT”) shown in FIG. 1 is performed to etch a film of a substrate. FIG. 2 is a partially enlarged cross sectional view of an example of a substrate to which the etching method shown in FIG. 1 is applicable. A substrate W shown in FIG. 2 has a film EF and a mask MK. The film EF is an etching target film and is provided on an underlying region UR. The film EF is a silicon-containing film. The film EF may be, but not limited to, a silicon oxide film, a silicon nitride film or a multilayered film including a plurality of silicon oxide films and a multiplicity of silicon nitride films. In the multilayered film, the plurality of silicon oxide films and the multiplicity of silicon nitride films are alternately stacked on top of each other. The mask MK is provided on the film EF. The mask MK is made of a carbon-containing material or polycrystalline silicon. The mask MK is provided with a pattern to be transferred to the film EF. A surface of the film EF is partially exposed through the pattern of the mask MK. The mask MK provides one or more openings such as a hole and/or a groove.

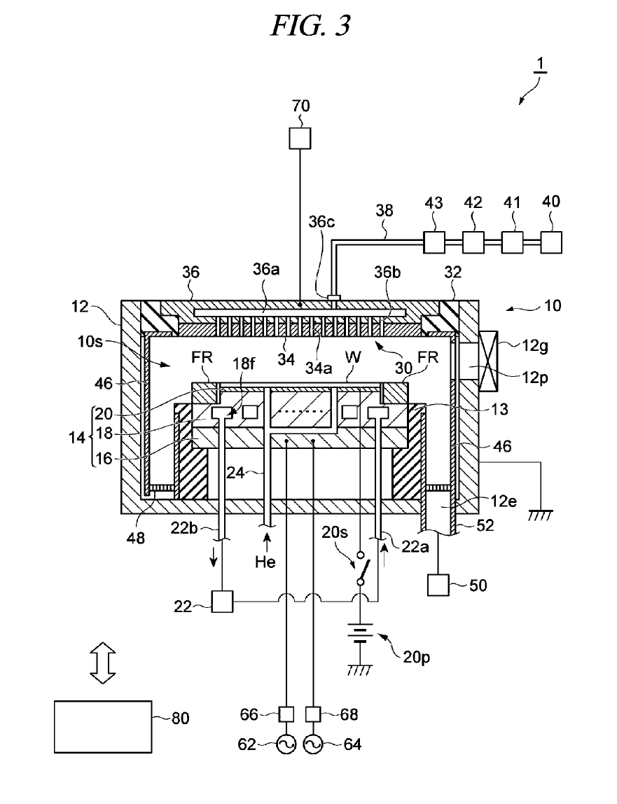

A plasma processing apparatus is used to perform the method MT. FIG. 3 is a diagram schematically illustrating an example of a plasma processing apparatus which can be used to perform the etching method shown in FIG. 1. A plasma processing apparatus 1 shown in FIG. 3 is configured as a capacitively coupled plasma etching apparatus. The plasma processing apparatus 1 is equipped with a chamber 10. The chamber 10 has an internal space 10s therein.

The chamber 10 includes a chamber main body 12. The chamber main body 12 has a substantially cylindrical shape. The internal space 10s is provided inside the chamber main body 12. The chamber main body 12 is made of, by way of non-limiting example, aluminum. A film having corrosion resistance is formed on an inner wall surface of the chamber main body 12. The film having the corrosion resistance may be a film made of ceramic such as aluminum oxide or yttrium oxide.

A passage 12p is formed at a sidewall of the chamber main body 12. When the substrate W is transferred between the internal space 10s and an outside of the chamber 10, the substrate W passes through the passage 12p. This passage 12p is opened or closed by a gate valve 12g. The gate valve 12g is provided along the sidewall of the chamber main body 12.

A supporting member 13 is provided on a bottom portion of the chamber main body 12. The supporting member 13 is made of an insulating material and has a substantially cylindrical shape. The supporting member 13 is extended upwards from the bottom portion of the chamber main body 12 within the internal space 10s. The supporting member 13 is configured to support a supporting table 14. The supporting table 14 is provided within the internal space 10s. The supporting table 14 is configured to support the substrate W within the internal space 10s.

The supporting table 14 includes a lower electrode 18 and an electrostatic chuck 20. The supporting table 14 may further include an electrode plate 16. The electrode plate 16 is made of a conductor such as, but not limited to, aluminum and has a substantially disk shape. The lower electrode 18 is provided on the electrode plate 16. The lower electrode 18 is made of a conductor such as, but not limited to, aluminum and has a substantially disk shape. The lower electrode 18 is electrically connected to the electrode plate 16.

The electrostatic chuck 20 is provided on the lower electrode 18. The substrate W is placed on a top surface of the electrostatic chuck 20. The electrostatic chuck 20 has a main body and an electrode. The main body of the electrostatic chuck 20 is made of a dielectric material. The electrode of the electrostatic chuck 20 is a film-shaped electrode and is provided within the main body of the electrostatic chuck 20. The electrode of the electrostatic chuck 20 is connected to a DC power supply 20p via a switch 20s. If a voltage from the DC power supply 20p is applied to the electrode of the electrostatic chuck 20, an electrostatic attracting force is generated between the electrostatic chuck 20 and the substrate W. Thus, the substrate W is attracted to and held by the electrostatic chuck 20 by the generated electrostatic attracting force.

A focus ring FR is provided on a peripheral portion of the lower electrode 18 to surround an edge of the substrate W. The focus ring FR is configured to improve uniformity of a plasma processing upon the substrate W within a surface thereof. The focus ring FR may be made of, but not limited to, silicon, silicon carbide or quartz.

A path 18f is provided within the lower electrode 18. A heat exchange medium (for example, a coolant) is supplied via a pipeline 22a into the path 18f from a chiller unit 22 provided at the outside of the chamber 10. The heat exchange medium supplied into the path 181 is returned back into the chiller unit 22 via a pipeline 22b. In the plasma processing apparatus 1, a temperature of the substrate W placed on the electrostatic chuck 20 is adjusted by a heat exchange between the heat exchange medium and the lower electrode 18.

The plasma processing apparatus 1 is equipped with a gas supply line 24. Through the gas supply line 24, a heat transfer gas (e.g., a He gas) from a heat transfer gas supply mechanism is supplied into a gap between the top surface of the electrostatic chuck 20 and a rear surface of the substrate W.

The plasma processing apparatus 1 is further equipped with an upper electrode 30. The upper electrode 30 is provided above the supporting table 14. The upper electrode 30 is supported at an upper portion of the chamber main body 12 with a member 32 therebetween. The member 32 is made of a material having insulation property. The upper electrode 30 and the member 32 close a top opening of the chamber main body 12.

The upper electrode 30 may include a ceiling plate 34 and a supporting body 36. A bottom surface of the ceiling plate 34 is a surface facing the internal space 10s, and forms and confines the internal space 10s. The ceiling plate 34 may be made of a conductor or a semiconductor having low Joule heat. The ceiling plate 34 is provided with multiple gas discharge holes 34a. These gas discharge holes 34a are formed through the ceiling plate 34 in a plate thickness direction.

The supporting body 36 is configured to support the ceiling plate 34 in a detachable manner, and is made of a conductive material such as, but not limited to, aluminum. A gas diffusion space 36a is provided within the supporting body 36. The supporting body 36 is provided with multiple gas holes 36b. The multiple gas holes 36b are extended downwards from the gas diffusion space 36a. The multiple gas holes 36b communicate with the multiple gas discharge holes 34a respectively. The supporting body 36 is provided with a gas inlet port 36c. The gas inlet port 36c is connected to the gas diffusion space 36a. A gas supply line 38 is connected to this gas inlet port 36c.

The gas supply line 38 is connected to a gas source group 40 via a valve group 41, a flow rate controller group 42 and a valve group 43. The gas source group 40 includes a plurality of gas sources. The plurality of gas sources belonging to the gas source group 40 include sources of gases for use in the method MT. Each of the valve groups 41 and 43 includes a plurality of opening/closing valves. The flow rate controller group 42 includes a plurality of flow rate controllers. Each of the plurality of flow rate controllers belonging to the flow rate controller group 42 may be a mass flow controller or a pressure control type flow rate controller. Each of the plurality of gas sources belonging to the gas source group 40 is connected to the gas supply line 38 via a corresponding opening/closing valve belonging to the valve group 41, a corresponding flow rate controller belonging to the flow rate controller group 42 and a corresponding opening/closing valve belonging to the valve group 43.

In the plasma processing apparatus 1, a shield 46 is provided along the inner wall surface of the chamber main body 12 in a detachable manner. The shield 46 is also provided on an outer side surface of the supporting member 13. The shield 46 is configured to suppress an etching byproduct from adhering to the chamber main body 12. The shield 46 is prepared by forming a film having corrosion resistance on a surface of a base member made of, by way of non-limiting example, aluminum. The film having corrosion resistance may be one made of ceramic such as yttrium oxide.

A baffle plate 48 is provided between the supporting member 13 and the sidewall of the chamber main body 12. The baffle plate 48 may be made of, by way of example, an aluminum base member on which a film having corrosion resistance is formed. The film having corrosion resistance may be one made of ceramic such as yttrium oxide. The baffle plate 48 is provided with a plurality of through holes. A gas exhaust port 12e is provided at the bottom portion of the chamber main body 12 under the baffle plate 48. The gas exhaust port 12e is connected with a gas exhaust device 50 via a gas exhaust line 52. The gas exhaust device 50 has a pressure control valve and a vacuum pump such as a turbo molecular pump.

The plasma processing apparatus 1 is further equipped with a first high frequency power supply 62 and a second high frequency power supply 64. The first high frequency power supply 62 is configured to generate a first high frequency power for plasma generation. A frequency of the first high frequency power is in a range from, e.g., 27 MHz to 100 MHz. The first high frequency power supply 62 is connected to the lower electrode 18 via a matching device 66 and the electrode plate 16. The matching device 66 is equipped with a circuit configured to match an output impedance of the first high frequency power supply 62 and an input impedance at a load side (lower electrode 18 side). Further, the first high frequency power supply 62 may be connected to the upper electrode 30 via the matching device 66.

The second high frequency power supply 64 is configured to generate a second high frequency power for ion attraction into the substrate W. A frequency of the second high frequency power is lower than the frequency of the first high frequency power. The frequency of the second high frequency power falls within a range from, e.g., 400 kHz to 13.56 MHz. The second high frequency power supply 64 is connected to the lower electrode 18 via a matching device 68 and the electrode plate 16. The matching device 68 is equipped with a circuit configured to match an output impedance of the second high frequency power supply 64 and the input impedance at the load side (lower electrode 18 side).

The plasma processing apparatus 1 may further include a DC power supply 70. The DC power supply 70 is connected to the upper electrode 30. The DC power supply 70 is configured to generate a negative DC voltage and apply the generated DC voltage to the upper electrode 30.

The plasma processing apparatus 1 may further include a control unit 80. The control unit 80 may be implemented by a computer including a processor, a storage unit such as a memory, an input device, a display device, a signal input/output interface, and so forth. The control unit 80 is configured to control individual components of the plasma processing apparatus 1. In the control unit 80, an operator can input commands through the input device to manage the plasma processing apparatus 1. Further, in the control unit 80, an operational status of the plasma processing apparatus 1 can be visually displayed on the display device. Further, the storage unit of the control unit 80 stores therein control programs and recipe data. The control programs are executed by the processor of the control unit 80 to perform various processings in the plasma processing apparatus 1. As the processor of the control unit 80 executes the control programs and controls the individual components of the plasma processing apparatus 1 according to the recipe data, the method MT is performed in the plasma processing apparatus 1.

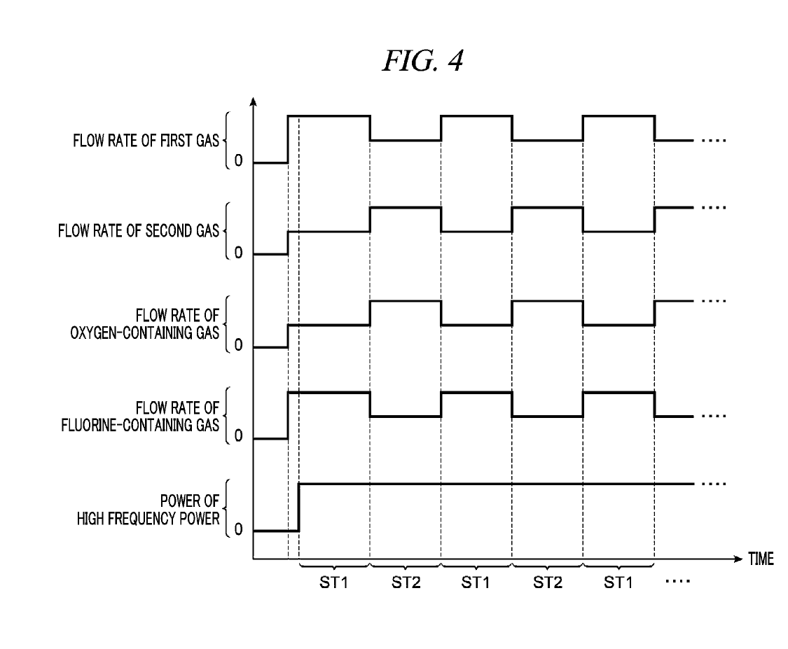

Now, the method MT will be described for an example case where the method MT is performed on the substrate W shown in FIG. 2 by using the plasma processing apparatus 1. The substrate to which the method MT is applied may not be particularly limited as long as the substrate has a film and a mask having a pattern to be transferred to the film. In the following description, reference is made of FIG. 4 as well as FIG. 1. FIG. 4 is a timing chart regarding the etching method shown in FIG. 1.

The method MT is performed in a state that the substrate W is placed within the chamber of the plasma processing apparatus 1, that is, within the internal space 10s. Within the internal space 10s, the substrate W is placed on and held by the electrostatic chuck 20. As shown in FIG. 1 and FIG. 4, the method MT includes a process ST1 and a process ST2. The process ST1 and the process ST2 are alternately performed.

In the process ST1, plasma of a first processing gas is generated within the chamber 10, that is, within the internal space 10s to etch the film EF. In the process ST2, plasma of a second processing gas is generated within the chamber 10, that is, within the internal space 10s to etch the film EF. Each of the first processing gas and the second processing gas includes a first gas, a second gas, an oxygen-containing gas and a fluorine-containing gas.

The first gas includes first fluorocarbon. The first fluorocarbon may be perfluorocarbon or hydrofluorocarbon. The second gas includes second fluorocarbon. The second fluorocarbon may be perfluorocarbon or hydrofluorocarbon. A value of a ratio of the number of fluorine atoms to the number of carbon atoms in a molecule of the second fluorocarbon is larger than a value of a ratio of the number of fluorine atoms to the number of carbon atoms in a molecule of the first fluorocarbon. As an example, the first fluorocarbon is C₄F₆, and the second fluorocarbon is C₄F₈. As another example, the first fluorocarbon is C₄F₆, and the second fluorocarbon is CHF₃. The oxygen-containing gas included in each of the first processing gas and the second processing gas may be an oxygen gas (O₂ gas), carbon monoxide gas or carbon dioxide gas. The fluorine-containing gas included in each of the first processing gas and the second processing gas may not be particularly limited and may be, by way of non-limiting example, a NF₃ gas or a SF₆ gas. As an example, each of the first processing gas and the second processing gas includes the first gas containing C₄F₆, the second gas containing C₄F₈, the oxygen gas (0₂ gas) and the NF₃ gas.

As shown in FIG. 4, a flow rate of the first gas in the first processing gas is larger than a flow rate of the first gas in the second processing gas. That is, the flow rate of the first gas in the process ST1 is larger than the flow rate of the first gas in the process ST2. Further, a flow rate of the second gas in the second processing gas is larger than a flow rate of the second gas in the first processing gas. That is, the flow rate of the second gas in the process ST2 is larger than the flow rate of the second gas in the process ST1. Further, a flow rate of the oxygen-containing gas in the second processing gas is larger than a flow rate of the oxygen-containing gas in the first processing gas. That is, the flow rate of the oxygen-containing gas in the process ST2 is larger than the flow rate of the oxygen-containing gas in the process ST1. In addition, a flow rate of the fluorine-containing gas in the second processing gas is smaller than a flow rate of the fluorine-containing gas in the first processing gas. That is, the flow rate of the fluorine-containing gas in the process ST2 is smaller than the flow rate of the fluorine-containing gas in the process ST1. Further, the flow rate of the first gas in the first processing gas is larger than the flow rate of the second gas in the first processing gas, and the flow rate of the second gas in the second processing gas is larger than the flow rate of the first gas in the second processing gas.

In the process ST1, the first processing gas is supplied into the internal space 10s from the gas source group 40. In the process ST1, the gas exhaust device 50 is controlled such that a pressure within the internal space 10s is set to be a preset pressure. In the process ST1, the first high frequency power is supplied to generate plasma of the first processing gas. In the process ST1, the second high frequency power may be supplied to the lower electrode 18.

In the process ST2, the second processing gas is supplied into the internal space 10s from the gas source group 40. In the process ST2, the gas exhaust device 50 is controlled such that the pressure within the internal space 10s is set to be a predetermined pressure. In the process ST2, the first high frequency power is supplied to generate plasma of the second processing gas. Further, in the process ST2, the second high frequency power is supplied to the lower electrode 18. In the exemplary embodiment, the first high frequency power is continuously supplied through the process ST1 and the process ST2, that is, through the alternate repetitions of the process ST1 and the process ST2. The second high frequency power may be continuously supplied through the process ST1 and the process ST2, that is, through the alternate repetitions of the process ST1 and the process ST2.

The flow rate of the first gas in the first processing gas is large, as compared to that in the second processing gas. The first gas contains a relatively large amount of carbon atoms. Accordingly, while the process ST1 is being performed, a deposit including a carbon-containing material, that is, a deposit containing carbon and/or carbon and fluorine is formed on the mask MK. The flow rate of the second gas in the second processing gas is large, as compared to that in the first processing gas. The second gas contains a relatively large amount of fluorine atoms. Accordingly, while the process ST2 is being performed, the film EF is etched. Further, during the process ST2, the mask MK is protected by the deposit formed in the process ST1.

In the method MT, an overshoot and an undershoot in a time characteristic of an emission intensity of fluorine in the plasma and a time characteristic of an emission intensity of oxygen in the plasma are suppressed. Further, each of the emission intensity of the fluorine in the plasma and the emission intensity of the oxygen in the plasma increases or decreases as time passes by. That is, it is possible to increase or decrease density of plasma of the fluorine and density of plasma of the oxygen with a lapse of time while suppressing an excessive variation in the density of the plasma of the fluorine and the density of the plasma of the oxygen. Thus, according to the method MT, the amount of the carbon-containing material deposited on the mask MK can be controlled. Therefore, it becomes possible to etch the film EF selectively with respect to the mask MK, that is, to achieve the high selectivity.

So far, various exemplary embodiments have been described. However, the above-described exemplary embodiments are not limiting, and various changes and modifications may be made. By way of example, the method MT may be performed by using any of various types of plasma processing apparatuses such as an inductively coupled plasma processing apparatus and a plasma processing apparatus configured to excite a gas by using a surface wave such as a microwave. Further, in the method MT, either the process ST1 or the process ST2 may be first performed.

Now, various experiments conducted to evaluate the method MT will be explained. Here, however, it should be noted that the present disclosure is not limited to the following experiments.

### First and Second Experiments, and First and Second Comparative Experiments

In a first experiment and a second experiment, the method MT is performed by using the plasma processing apparatus 1 under the following conditions. Then, the time characteristics (time variations) of the emission intensity of a wavelength of 704 nm (emission intensity of fluorine F), the emission intensity of a wavelength of 777 nm (emission intensity of oxygen O) and the emission intensity of a wavelength of 516 nm (emission intensity of C₂) in the internal space 10s are measured.

### Conditions for First Experiment

### Process ST1

C₄F₆ gas: 87 sccm
C₄F₈ gas: 17 sccm
O₂ gas: 47 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 60 sec

### Process ST2

C₄F₆ gas: 17 sccm
C₄F₈ gas: 87 sccm
O₂ gas: 87 sccm
NF₃ gas: 5 sccm
Pressure within internal space 10s: 1.33 Pa (10 mTorr)
First high frequency power: 40 MHz, 1500 W
Second high frequency power: 400 kHz, 14000 W
Processing time: 60 sec

### Conditions for Second Experiment

### Process ST1

C₄F₆ gas: 87 sccm
CHF₃ gas: 34 sccm
O₂ gas: 47 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 60 sec

### Process ST2

C₄F₆ gas: 17 sccm
CHF₃ gas: 174 sccm
O₂ gas: 87 sccm
NF₃ gas: 5 sccm
Pressure within internal space 10s: 1.33 Pa (10 mTorr)
First high frequency power: 40 MHz, 1500 W
Second high frequency power: 400 kHz, 14000 W
Processing time: 60 sec

In a first comparative experiment and a second comparative experiment, a first process and a second process specified as follows are alternately repeated by using the plasma processing apparatus 1. Then, the time characteristics (time variations) of the emission intensity of the wavelength of 704 nm (emission intensity of fluorine F), the emission intensity of the wavelength of 777 nm (emission intensity of oxygen O) and the emission intensity of the wavelength of 516 nm (emission intensity of C₂) in the internal space 10s are measured.

### Conditions for First Comparative Experiment

### First Process

C₄F₆ gas: 87 sccm
C₄F₈ gas: 17 sccm
O₂ gas: 47 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 60 sec

### Second Process

C₄F₆ gas: 17 sccm
C₄F₈ gas: 87 sccm
O₂ gas: 47 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 60 sec

### Conditions for Second Comparative Experiment

### First Process

C₄F₆ gas: 87 sccm
C₄F₈ gas: 17 sccm
O₂ gas: 47 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 60 sec

### Second Process

C₄F₆ gas: 17 sccm
C₄F₈ gas: 87 sccm
O₂ gas: 87 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 60 sec

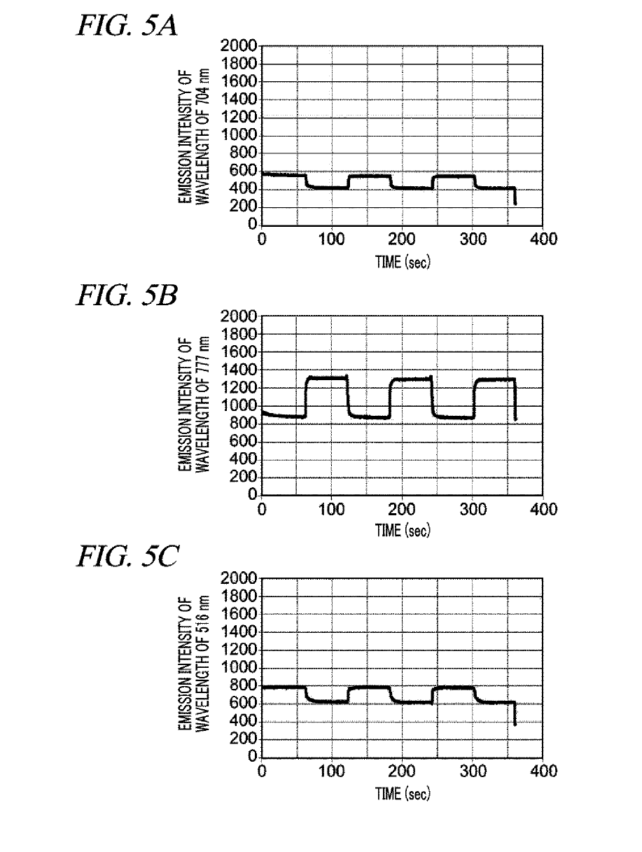

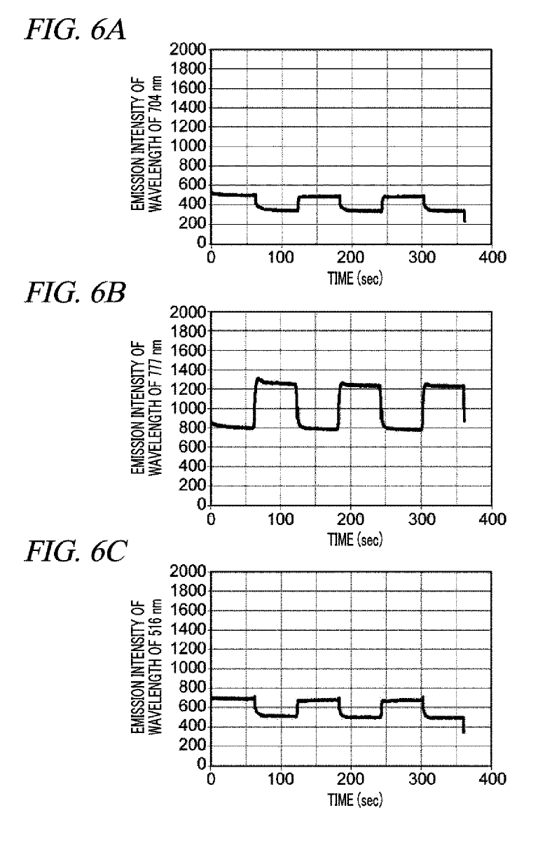

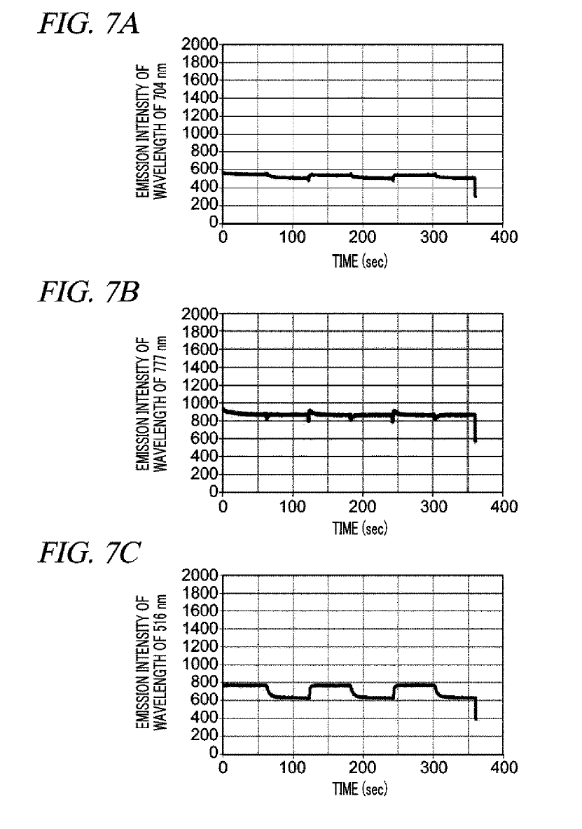

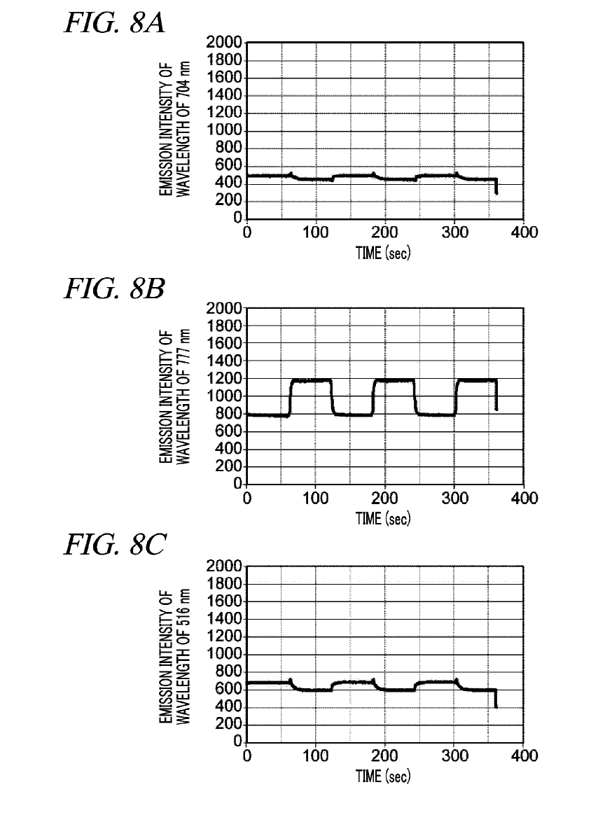

FIG. 5A is a graph showing the time characteristic of the emission intensity of the wavelength of 704 nm measured in the first experiment; FIG. 5B, a graph showing the time characteristic of the emission intensity of the wavelength of 777 nm measured in the first experiment; and FIG. 5C, a graph showing the time characteristic of the emission intensity of the wavelength of 516 nm measured in the first experiment. FIG. 6A is a graph showing the time characteristic of the emission intensity of the wavelength of 704 nm measured in the second experiment; FIG. 6B, a graph showing the time characteristic of the emission intensity of the wavelength of 777 nm measured in the second experiment; and FIG. 6C, a graph showing the time characteristic of the emission intensity of the wavelength of 516 nm measured in the second experiment. FIG. 7A is a graph showing the time characteristic of the emission intensity of the wavelength of 704 nm measured in the first comparative experiment; FIG. 7B, a graph showing the time characteristic of the emission intensity of the wavelength of 777 nm measured in the first comparative experiment; and FIG. 7C, a graph showing the time characteristic of the emission intensity of the wavelength of 516 nm measured in the first comparative experiment. FIG. 8A is a graph showing the time characteristic of the emission intensity of the wavelength of 704 nm measured in the second comparative experiment; FIG. 8B, a graph showing the time characteristic of the emission intensity of the wavelength of 777 nm measured in the second comparative experiment; and FIG. 8C, a graph showing the time characteristic of the emission intensity of the wavelength of 516 nm measured in the second comparative experiment.

In the first comparative experiment, the flow rate of the O₂ gas and the flow rate of the NF₃ gas are not changed throughout the first process and the second process. In the first comparative experiment, an overshoot and an undershoot are found in the time characteristic of the emission intensity of the fluorine and the time characteristic of the emission intensity of the oxygen, as shown in FIG. 7A and FIG. 7B. In the second comparative experiment, though the flow rate of the O₂ gas in the second process is increased with respect to the flow rate of the O₂ gas in the first process, the flow rate of the NF₃ gas is not changed throughout the first process and the second process. In this second comparative experiment, an overshoot and an undershoot are found in the time characteristic of the emission intensity of the fluorine, as depicted in FIG. 8A. In the first comparative experiment and the second comparative experiment, the processing time of the first process and the processing time of the second process are respectively set to be 60 seconds which is relatively long. If, however, the processing time of the first process and the processing time of the second process are short, a state in which the emission intensity of the fluorine and the emission intensity of the oxygen are relatively high is maintained in each of the first process and the second process due to an influence of the overshoot. That is, in case that the processing time of the first process and the processing time of the second process are short, the state in which the density of the plasma of the fluorine and the density of the plasma of the oxygen are relatively high is maintained in each of the first process and the second process. Accordingly, if the flow rate of the O₂ gas and the flow rate of the NF₃ gas are not changed throughout the first process and the second process and if the flow rate of the NF₃ gas is not changed throughout the first process and the second process, the mask is etched, so that the selectivity is deteriorated.

Meanwhile, in the first experiment and the second experiment, the time characteristic of the emission intensity of the fluorine and the time characteristic of the emission intensity of the oxygen exhibit neither the overshoot nor the undershoot, as can be seen from FIG. 5A, FIG. 5B, FIG. 6A and FIG. 6B. Further, the emission intensity of the fluorine is found to increase or decrease apparently in the time characteristic of the emission intensity of the fluorine, and the emission intensity of the oxygen is found to increase or decrease apparently in the time characteristic of the emission intensity of the oxygen. Thus, it is found out that, according to the method MT, the density of the plasma of the fluorine and the density of the plasma of the oxygen can be increased or decreased while suppressing the excessive variations in the density of the plasma of the fluorine and the density of the plasma of the oxygen.

### Third Experiment and Third Comparative Experiment

In a third experiment, a film of a sample substrate is etched by performing the method MT in the plasma processing apparatus 1 under the following conditions. The sample substrate has the etching target film; and a mask provided on the etching target film. The etching target film of the sample substrate is a silicon oxide film. The mask of the sample substrate is made of polycrystalline silicon. In the third experiment, a ratio of a decrement of a film thickness of the etching target film of the sample substrate by the etching to a decrement of a film thickness of the mask of the sample substrate by the etching, that is, a selectivity is calculated.

### Conditions for Third Experiment

### Process ST1

C₄F₆ gas: 97 sccm
C₄F₈ gas: 7 sccm
O₂ gas: 27 sccm
NF₃ gas: 35 sccm
Pressure within internal space 10s: 1.33 Pa (10 mTorr)
First high frequency power: 40 MHz, 1500 W
Second high frequency power: 400 kHz, 14000 W
Processing time: 5 sec

### Process ST2

C₄F₆ gas: 27 sccm
C₄F₈ gas: 77 sccm
O₂ gas: 67 sccm
NF₃ gas: 5 sccm
Pressure within internal space 10s: 1.33 Pa (10 mTorr)
First high frequency power: 40 MHz, 1500 W
Second high frequency power: 400 kHz, 14000 W
Processing time: 5 sec
Number of alternate repetitions of process ST1 and process ST2: 9 times

In a third comparative experiment, an etching target film of a sample substrate, which is the same as the sample substrate of the third experiment, is etched by performing a first process and a second process as follows alternately in the plasma processing apparatus 1. In the third comparative experiment, a ratio of a decrement of a film thickness of the etching target film of the sample substrate by the etching to a decrement of a film thickness of the mask of the sample substrate by the etching, that is, a selectivity is calculated.

### Conditions for Third Comparative Experiment

### First Process

C₄F₆ gas: 77 sccm
C₄F₈ gas: 27 sccm
O₂ gas: 47 sccm
NF₃ gas: 5 sccm
Pressure within internal space 10s: 1.33 Pa (10 mTorr)
First high frequency power: 40 MHz, 1500 W
Second high frequency power: 400 kHz, 14000 W
Processing time: 5 sec

### Second Process

C₄F₆ gas: 27 sccm
C₄F₈ gas: 77 sccm
O₂ gas: 47 sccm
NF₃ gas: 5 sccm
Pressure within internal space 10s: 1.33 Pa (10 mTorr)
First high frequency power: 40 MHz, 1500 W
Second high frequency power: 400 kHz, 14000 W
Processing time: 5 sec
Number of alternate repetitions of first process and second process: 9 times

In the third experiment, the selectivity is found to be 4.03. Meanwhile, in the third comparative experiment, the selectivity is found to be 3.18. That is, the selectivity in the third experiment is found to be improved by about 27% as compared to the selectivity in the third comparative experiment. Thus, it is found out that the selectivity can be improved according to the method MT.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. An etching method of etching a film of a substrate,
wherein the substrate has a mask provided with a pattern on the film and the etching method is performed in a state that the substrate is placed in a chamber of a plasma processing apparatus, and
wherein the etching method comprises:
generating plasma of a first processing gas including a first gas containing first fluorocarbon, a second gas containing second fluorocarbon, an oxygen-containing gas and a fluorine-containing gas within the chamber to etch the film; and
generating plasma of a second processing gas including the first gas, the second gas, the oxygen-containing gas and the fluorine-containing gas within the chamber to etch the film,
wherein the generating of the plasma of the first processing gas and the generating of the plasma of the second processing gas are performed alternately,
a ratio of a number of fluorine atoms to a number of carbon atoms in a molecule of the second fluorocarbon is larger than a ratio of the number of fluorine atoms to the number of carbon atoms in a molecule of the first fluorocarbon,
a flow rate of the first gas in the first processing gas is larger than a flow rate of the first gas in the second processing gas,
a flow rate of the second gas in the second processing gas is larger than a flow rate of the second gas in the first processing gas,
a flow rate of the oxygen-containing gas in the second processing gas is larger than a flow rate of the oxygen-containing gas in the first processing gas, and
a flow rate of the fluorine-containing gas in the second processing gas is smaller than a flow rate of the fluorine-containing gas in the first processing gas.

2. The etching method of claim 1,
wherein a high frequency power for generation of the plasma of the first processing gas and generation of the plasma of the second processing gas is continuously supplied through the generating of the plasma of the first processing gas and the generating of the plasma of the second processing gas.

3. The etching method of claim 1,
wherein the flow rate of the first gas in the first processing gas is larger than the flow rate of the second gas in the first processing gas, and
the flow rate of the second gas in the second processing gas is larger than the flow rate of the first gas in the second processing gas.

4. The etching method of claim 1,
wherein the first fluorocarbon is perfluorocarbon or hydrofluorocarbon, and
the second fluorocarbon is perfluorocarbon or hydrofluorocarbon.

5. The etching method of claim 4,
wherein the first fluorocarbon is C₄F₆.

6. The etching method of claim 4,
wherein the second fluorocarbon is C₄F₈.

7. The etching method of claim 1,
wherein the oxygen-containing gas is an oxygen gas.

8. The etching method of claim 1,
wherein the fluorine-containing gas is a NF₃ gas.
